(19) United States
(12) Patent Application Publication
(10) Pub. No.: US 2026/0286505 A1
(43) Pub. Date: Sep. 24, 2026

(54) TARGET FOR FILM DEPOSITION AND METHOD FOR PRODUCING FUNCTIONAL LAYER

(71) Applicant: NIPPON ELECTRIC GLASS CO., LTD., Otsu-shi, Shiga (JP)

(72) Inventors: Yoshimasa MATSUSHITA, Otsu-shi (JP); Kosuke KARAKIDA, Otsu-shi (JP); Fumio SATO, Otsu-shi (JP)

(21) Appl. No.: 19/477,155

(22) PCT Filed: May 16, 2024
(86) PCT No.: PCT/JP2024/018186

§ 371 Date: Oct. 21, 2025

(30) Foreign Application Priority Data
May 18, 2023 (JP) 2023-082043
Jul. 21, 2023 (JP) 2023-118830

(51) Int. Cl. C23C 14/34; H10B 63/00; H10N 70/00; H10N 70/20

(52) U.S. Cl. CPC C23C 14/3407; H10N 70/026; H10B 63/24; H10N 70/231; H10N 70/25

(57) ABSTRACT

Provided are a target for film deposition and a method for producing a functional layer, both of which are suitable for production of a large-capacity memory device and an OTS element exhibiting a stable switching behavior. A target for film deposition contains, in terms of atomic %, 0.1% to 50% Ge, 40% to 90% Te, and 1% to 59% Si+Al+Ga+Sn+Bi+Cu+Ag+Zn+Y+In+Ca+Mg and is substantially free of Sb.

### TECHNICAL FIELD

The present invention relates to targets for film deposition and methods for producing functional layers.

### BACKGROUND ART

Next-generation non-volatile memory devices are attracting attention as alternative memory devices to a NAND flash memory. For example, a phase-change memory device is proposed as a next-generation non-volatile memory device. The phase-change memory device includes a functional layer made of a phase-change material and records information using a difference in electrical resistance between an amorphous state and a crystalline state of the phase-change material.

Furthermore, a cross-point memory device is also attracting attention as a structure for a next-generation non-volatile memory device (Patent Literatures 1 and 2). The cross-point memory device includes word lines, bit lines orthogonal to the word lines in plan view, and memory elements and switch elements arranged at the intersections between the word lines and the bit lines in plan view. An ovonic threshold switch element (OTS element) is proposed as a switch element. The OTS element includes a functional layer made of a variable-resistance material and obtains a switching behavior using changes in resistance with the application of voltage.

### CITATION LIST

### Patent Literature

[PTL 1]
JP-A-2006-086526
[PTL 2]
JP-A-2018-164085

### SUMMARY OF INVENTION

### Technical Problem

The phase-change memory device is required to stabilize the amorphous state for the purpose of achieving an even larger capacity. Furthermore, the OTS element is required to exhibit stable resistance changes with applied voltage for the purpose of obtaining a stable switching behavior.

In view of the foregoing, the present invention has an object of providing a target for film deposition and a method for producing a functional layer, both of which are suitable for production of a large-capacity memory device and an OTS element exhibiting a stable switching behavior.

### Solution to Problem

A description will be given below of aspects of a target for film deposition and a method for producing a functional layer, both of which can solve the above problem.

A target for film deposition of aspect 1 contains, in terms of atomic %, 0.1% to 50% Ge, 40% to 90% Te, and 1% to 59% Si+Al+Ga+Sn+Bi+Cu+Ag+Zn+Y+In+Ca+Mg and is substantially free of Sb.

A target for film deposition of aspect 2 is made of a bulk chalcogenide glass containing, in terms of atomic %, 0.1% to 50% Ge, 40% to 90% Te, and 1% to 59% Si+Al+Ga+Sn+Bi+Cu+Ag+Zn+Y+In+Ca+Mg and being substantially free of Sb.

A target for film deposition of aspect 3 contains, in terms of atomic %, 0.1% to 50% Ge, 40% to 90% Te, and 1% to 59% Si+Al+Ga+Sn+Bi+Cu+Ag+Zn+Y+In+Ca+Mg, is substantially free of Sb, and contains a crystal portion.

A target for film deposition of aspect 4 is the target for film deposition according to any one of aspects 1 to 3 and preferably has a relative density of not less than 90%.

A target for film deposition of aspect 5 is the target for film deposition according to any one of aspects 1 to 4 and preferably has an oxygen content of, in terms of atomic %, not less than 0.001 ppm and less than 1%.

A target for film deposition of aspect 6 is the target for film deposition according to any one of aspects 1 to 5, wherein a difference Δ (Tm−Tx) between a crystalline melting point Tm and a crystallization temperature Tx is preferably not higher than 500° C.

A target for film deposition of aspect 7 is the target for film deposition according to any one of aspects 1 to 6 and is preferably used for production of a variable-resistance layer.

A target for film deposition of aspect 8 is the target for film deposition according to any one of aspects 1 to 7 and preferably has a disc shape with a diameter of 20 mm to 300 mm, a thickness of 1 mm to 100 mm, and a surface roughness of less than 500 μm.

A target for film deposition of aspect 9 is the target for film deposition according to any one of aspects 1 to 8 and preferably further includes a substrate.

A method for producing a functional layer of aspect 10 is a method for producing a functional layer using a target for film deposition, the target for film deposition being made of a bulk chalcogenide glass containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb, and includes producing a functional layer containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb.

A method for producing a functional layer of aspect 11 is the method for producing a functional layer according to aspect 10, wherein a second target for film deposition is preferably further provided.

A method for producing a functional layer of aspect 12 is the method for producing a functional layer according to aspect 10 or 11, wherein the functional layer is preferably a variable-resistance layer.

A method for producing a functional layer of aspect 13 is the method for producing a functional layer according to aspect 10 or 11, wherein the functional layer is preferably a phase-change layer.

A method for producing a functional layer of aspect 14 is a method for producing a functional layer using a plurality of targets for film deposition, wherein the targets for film deposition include a target for film deposition made of a Ga alloy or a Ga compound and the functional layer is a variable-resistance layer or a phase-change layer each of which contains, in terms of atomic %, 0.1% to 50% Ge, 0.1% to 50% Ga, and 40% to 90% Te.

A method for producing a functional layer of aspect 15 is the method for producing a functional layer according any one of aspects 10 to 14, wherein the functional layer is preferably substantially free of Sb.

### Advantageous Effects of Invention

The present invention enables provision of a target for film deposition and a method for producing a functional layer, both of which are suitable for production of a large-capacity memory device and an OTS element exhibiting a stable switching behavior.

### BRIEF DESCRIPTION OF DRAWINGS

FIG. 1 is a schematic cross-sectional view of a switch element according to one embodiment of the present invention.

FIG. 2 is a schematic cross-sectional view of a memory element according to a first embodiment of the present invention.

FIG. 3 is a schematic stereogram of a memory device according to a first embodiment of the present invention.

FIG. 4 is a schematic stereogram of the memory device according to the first embodiment of the present invention.

FIG. 5 is a schematic stereogram of a modification of the memory device according to the first embodiment of the present invention.

FIG. 6 is a schematic cross-sectional view of a memory element according to a second embodiment of the present invention.

FIG. 7 is a schematic stereogram of a memory device according to a second embodiment of the present invention.

FIG. 8 is a schematic stereogram of a modification of the memory device according to the second embodiment of the present invention.

### DESCRIPTION OF EMBODIMENTS

Hereinafter, a description will be given of preferred embodiments. However, the following embodiments are merely illustrative and the present invention is not limited to the following embodiments.

### <Target for Film Deposition>

A target for film deposition according to the present invention contains, in terms of atomic %, 0.1% to 50% Ge, 40% to 90% Te, and 1% to 59% Si+Al+Ga+Sn+Bi+Cu+Ag+Zn+Y+In+Ca+Mg and is substantially free of Sb. With the use of a target for film deposition having the above composition, a functional layer suitable for a large-capacity memory device and an OTS element exhibiting a stable switching behavior can be produced. The functional layer is preferably a variable-resistance layer or a phase-change layer. In the following description, the OTS element is described also as a switch element.

In a certain wide aspect, the target for film deposition according to the present invention preferably contains, in terms of atomic %, 0.1% to 50% Ge and 40% to 90% Te and at least partly contains a chalcogenide glass. In other words, the target for film deposition according to the present invention preferably contains a glass portion containing, in terms of atomic %, 0.1% to 50% Ge and 40% to 90% Te. For example, the target for film deposition according to the present invention preferably contains a glass portion containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb. The target for film deposition containing the glass portion can be reduced in variations in density and components and can be easily increased in homogeneity. Furthermore, it has a high relative density and can be easily increased in mechanical strength.

In a certain wide aspect, the target for film deposition according to the present invention is preferably made of a bulk chalcogenide glass. For example, the target for film deposition according to the present invention is preferably made of a bulk chalcogenide glass containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb. Herein, bulk means that the thickness is not less than 0.1 mm. The target for film deposition made of a bulk chalcogenide glass can be easily increased in homogeneity and can be easily increased in mechanical strength. Furthermore, a later-described concavo-convex shape can be easily formed in a surface of the target for film deposition and the production life can be easily increased.

In a certain wide aspect, the target for film deposition according to the present invention preferably at least partly contains a crystallized chalcogenide glass. In other words, the target for film deposition according to the present invention preferably contains: a glass portion containing, in terms of atomic %, 0.1% to 50% Ge and 40% to 90% Te; and a crystal portion. For example, the target for film deposition according to the present invention preferably contains: a glass portion containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb; and a crystal portion. For example, the crystallized chalcogenide glass preferably has a structure in which 10% by volume or more of a chalcogenide glass (the glass portion) is crystallized, and more preferably has a structure in which 50% by volume or more of the chalcogenide glass is crystallized. The target for film deposition containing the crystal portion can be easily increased in mechanical strength. The crystal portion is preferably Ge-based crystals or Te-based crystals.

In a certain wide aspect, the target for film deposition according to the present invention may have a structure formed of a sintered or powder compact containing chalcogenide glass powder. For example, the target for film deposition according to the present invention is preferably formed of a sintered or powder compact that contains chalcogenide glass powder containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb. The target for film deposition which is a sintered or powder compact containing chalcogenide glass powder is advantageous for reducing the production cost and can be easily increased in diameter.

In the above structure, the target for film deposition may contain any kind of powder other than chalcogenide glass powder (any other kind of powder). The target for film deposition may contain, for example, metallic powder as the other kind of powder. For example, the target for film deposition according to the present invention is preferably formed of a sintered or powder compact of a mixture that contains: chalcogenide glass powder containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb; and metallic powder. The metallic powder may be metallic powder composed of a single-component metal or alloy powder. For example, the metallic powder may be Ge powder, Te powder or Ge—Te alloy powder. The target for film deposition may be a sintered compact of a mixture of chalcogenide glass powder and metallic powder or may be a powder compact of a mixture of chalcogenide glass powder and metallic powder.

In a certain wide aspect, the target for film deposition according to the present invention may have a structure free of chalcogenide glass. In other words, the target for film deposition according to the present invention may have a structure free of glass portion. For example, the target for film deposition according to the present invention may have a structure formed of a sintered powder compact or powder compact of metallic powder and free of glass portion. For example, the target for film deposition according to the present invention preferably contains, in terms of atomic %, 0.1% to 50% Ge, 40% to 90% Te, and 1% to 59% Si+Al+Ga+Sn+Bi+Cu+Ag+Zn+Y+In+Ca+Mg, is substantially free of Sb, and is formed of a sintered or powder compact of metallic powder. The metallic powder may be metallic powder composed of a single-component metal or alloy powder. For example, the metallic powder may be Ge powder, Te powder or Ge—Te alloy powder. Alternatively, the target for film deposition may be a metallic plate (of a single-element metal or an alloy) processed into a desired shape.

The relative density of the target for film deposition according to the present invention is preferably not less than 90%, more preferably not less than 91%, even more preferably not less than 92%, still even more preferably not less than 95%, and particularly preferably not less than 98%. The target for film deposition satisfying this structure has a small amount of voids and can be easily deposited into a homogeneous film. The upper limit of the relative density is not particularly limited, but may be, for example, not more than 100%, not more than 99.9% or particularly not more than 99%. Herein, the relative density means a value obtained by dividing an actually measured density measured by the Archimedes' ‘method by a theoretical density. The theoretical density can be calculated from the composition of the target for film deposition.

From the viewpoint of reducing the production cost, the target for film deposition according to the present invention has an oxygen content of, in terms of atomic %, preferably not less than 0.001 ppm, more preferably not less than 0.01 ppm, and particularly preferably not less than 0.1 ppm. On the other hand, from the viewpoint of reducing the production of oxygen impurities, the oxygen content is preferably less than 1%, not more than 0.8%, not more than 0.5%, not more than 0.3%, not more than 1000 ppm, not more than 500 ppm or not more than 100 ppm, and particularly preferably not more than 50 ppm. The oxygen content of the target for film deposition can be evaluated, for example, using the inert gas fusion-infrared ray absorptiometry.

Regarding the target for film deposition according to the present invention, the difference Δ (Tm−Tx) between the crystalline melting point Tm and the crystallization temperature Tx is preferably not higher than 500° C., more preferably not higher than 400° C., even more preferably not higher than 300° C., and particularly preferably not higher than 250° C. The lower limit of Δ (Tm−Tx) is not particularly limited, but may be, for example, not lower than 30° C., not lower than 50° C., not lower than 60° C. or particularly not lower than 80° C. The target for film deposition having the above value of Δ (Tm−Tx) is suitable for production of a phase-change layer.

Regarding the target for film deposition according to the present invention, the crystalline melting point Tm is preferably not higher than 600° C., not higher than 550° C., not higher than 500° C., not higher than 450° C., not higher than 430° C. or not higher than 410° C., and particularly preferably not higher than 400° C. A functional layer deposited using the target for film deposition having the above structure can reduce the energy necessary for phase change. In order to bring Δ (Tm−Tx) to a desired value, the lower limit of the crystalline melting point Tm is, for example, preferably not lower than 250° C., not lower than 260° C., not lower than 280° C., not lower than 300° C., not lower than 320° C., not lower than 340° C. or not lower than 360° C., and particularly preferably not lower than 370° C.

Regarding the target for film deposition according to the present invention, the crystallization temperature Tx is preferably not lower than 160° C., not lower than 170° C., not lower than 175° C., not lower than 180° C., not lower than 185° C., not lower than 190° C., not lower than 195° C., not lower than 200° C. or not lower than 205° C., and particularly preferably not lower than 210° C. A functional layer deposited using the target for film deposition having the above structure can easily stabilize the amorphous state. The upper limit of the crystallization temperature Tx is not particularly limited, but may be, for example, not higher than 600° C., not higher than 500° C. or particularly not higher than 450° C. In order to bring Δ (Tm−Tx) to a desired value, the upper limit of the crystallization temperature Tx is, for example, preferably not higher than 400° C., more preferably not higher than 350° C., and particularly preferably not higher than 300° C.

The crystalline melting point Tm and the crystallization temperature Tx of the target for film deposition can be evaluated using differential thermal analysis (DTA) or differential scanning calorimetry (DSC). Alternatively, the crystallization temperature Tx may be evaluated by determining the dependence of electrical resistance on temperature by the two-terminal method and regarding the temperature at which the electrical resistance rapidly drops as the crystallization temperature Tx. Still alternatively, the target for film deposition may be heat-treated at a predetermined temperature and the point at which a crystallization peak appears by XRD may be evaluated as the crystallization temperature Tx. It is preferred that the crystallization temperature Tx evaluated by any one of the above-described methods meets any one of the above-described ranges.

The target for film deposition according to the present invention can be used suitably for production of a variable-resistance layer. However, the target for film deposition according to the present invention may be used for production of a phase-change layer.

The target for film deposition according to the present invention preferably has a disc shape. For example, the target for film deposition preferably has a disc shape with a diameter of 20 mm to 300 mm, a thickness of 0.1 mm to 100 mm, and a surface roughness of less than 500 μm. However, the shape of the target for film deposition is not limited to the disc shape and may be, for example, a plate-like shape, a rectangular plate-like shape or a cylindrical shape. In these cases, the diameter of the target for film deposition can be substituted with the length thereof.

The diameter of the target for film deposition can be appropriately designed according to the size of a functional layer to be produced. For example, the diameter of the target for film deposition is preferably not less than 20 mm, more preferably not less than 30 mm, and particularly preferably not less than 50 mm. The upper limit of the diameter of the target for film deposition is not particularly limited, but is, for example, preferably not more than 300 mm, more preferably not more than 280 mm, and particularly preferably not more than 260 mm.

The thickness of the target for film deposition is preferably not less than 0.1 mm, more preferably not less than 0.5 mm, even more preferably not less than 1 mm, still even more preferably not less than 2 mm, yet still even more preferably not less than 4 mm, particularly preferably not less than 5 mm, preferably not more than 100 mm, more preferably not more than 90 mm, even more preferably not more than 80 mm, and particularly preferably not more than 50 mm. If the thickness of the target for film deposition is too small, the mechanical strength is likely to decrease. If the thickness of the target for film deposition is too large, the production cost for the target for film deposition is likely to increase.

The surface roughness of the target for film deposition is preferably less than 500 μm, more preferably not more than 400 μm, even more preferably not more than 300 μm, particularly preferably not more than 200 μm, preferably not less than 10 μm, more preferably not less than 20 μm, and particularly preferably not less than 50 μm. If the surface roughness of the target for film deposition is too small, the production cost for the target for film deposition is likely to increase. If the surface roughness of the target for film deposition is too large, particles are likely to be produced during film deposition, which makes it difficult to obtain a homogeneous functional layer.

The target for film deposition according to the present invention may have a concavo-convex structure in the surface thereof. For example, when the target for film deposition is subjected to magnetron sputtering, its surface is eroded (undergoes erosion). If the erosion progresses, an abnormal discharge or a change in sputtering rate may occur to result in the need for an exchange of the target for film deposition, which leads to an increased film deposition cost. Therefore, a concavo-convex shape to meet an erosional region is previously formed on the target for film deposition and, thus, the product life of the target for film deposition and the production efficiency of functional layers can be increased. In a target for film deposition at least partly containing a chalcogenide glass and a target for film deposition made of a bulk chalcogenide glass, a concavo-convex structure can be easily formed in the surface by press forming.

From the viewpoint of increasing the mechanical strength of the target for film deposition, the target for film deposition according to the present invention preferably further includes a substrate. The material for the substrate is not particularly limited, but one of a metallic material, a ceramic material, and quartz glass is preferably used. Preferred metallic materials that can be used include copper, molybdenum, and aluminum. An example of the preferred ceramic material that can be used is alumina.

Particularly, from the viewpoint of reducing the breakage of the target for film deposition, the thickness of the substrate is preferably not less than 100 μm, more preferably not less than 200 μm, even more preferably not less than 500 μm, still even more preferably not less than 800 μm, and particularly preferably not less than 1000 μm. The upper limit of the thickness of the substrate is not particularly limited, but may be, for example, not more than 10 mm, not more than 5 mm or particularly not more than 2 mm.

Hereinafter, the reasons why the composition of the target for film deposition is defined as described above and the respective contents of components will be described below. In the following description, “%” refers to “atomic %” unless otherwise stated. In the present invention, “x+y+z+ . . . ” means the total content of components. In this case, the target for film deposition need not necessarily contain all of the components as essential components and may not be free of one or some of the components (that is, the content of the one or some of the components may be 0%). The expression “A % to B % x+y+z+ . . . ” includes, for example, the case of “x=0% and A % to B % y+z+ . . . ” and the case of “x=0%, y=0%, and A % to B % z+ . . . ”.

Ge is a component that stabilizes the amorphous states of the target for film deposition and the functional layer. The content of Ge is preferably 0.1% to 50%. More specifically, the content of Ge is preferably not less than 0.1%, not less than 1%, not less than 3%, not less than 5%, not less than 7%, not less than 10%, not less than 11% or not less than 13%, particularly preferably not less than 15%, preferably not more than 50%, not more than 40% or not more than 30%, and particularly preferably not more than 20%. If the content of Ge is too small, the amorphous state is likely to be unstable. If the content of Ge is too large, the OTS characteristics are difficult to obtain. In addition, the production cost is likely to increase.

The OTS characteristics mean characteristics that the resistance value changes with the application of voltage. The details are as follows. A variable-resistance material exhibits high resistivity in an initial state (an OFF state). When the voltage applied to the material in this state is gradually increased, the material maintains a high-resistance state until a threshold voltage is reached, but switches rapidly to a low-resistance state (an ON state) when the threshold voltage is exceeded. When in the ON state the applied voltage is decreased, the material returns to the OFF state. Therefore, the material having the OTS characteristics can be used as a switch layer or a switch element. The larger the ON/OFF current ratio, the more excellent the characteristics as a switch element. The ON current value means a value (ON current value) of a current that flows through the switch layer or the switch element upon application of a voltage not less than the threshold voltage thereto. The OFF current value means a value (OFF current value) of a current that flows through the switch layer or the switch element upon application of one-half the threshold voltage thereto. The ON/OFF current ratio means a value obtained by dividing the ON current value by the OFF current value.

Te is an essential constituent of the target for film deposition and the functional layer. The content of Te is preferably 40% to 90%. More specifically, the content of Te is preferably not less than 40%, not less than 42%, not less than 47%, not less than 50%, more than 50%, not less than 51%, not less than 53%, not less than 55%, not less than 60%, not less than 61%, not less than 65%, not less than 67% or not less than 70%, particularly preferably not less than 71%, preferably not more than 90%, not more than 89%, not more than 85% or not more than 82.5%, and particularly preferably not more than 80%. If the content of Te is too small, the amorphous state is likely to be unstable. Furthermore, the OTS characteristics are difficult to obtain. If the content of Te is too large, the amorphous state is likely to be unstable. Furthermore, the OFF current value is likely to be large and the OTS characteristics are difficult to obtain.

The content of Ge+Te (the total content of Ge and Te) is preferably not less than 41%, not less than 45%, not less than 50%, not less than 60%, not less than 65%, not less than 70% or not less than 75%, particularly preferably not less than 80%, preferably not more than 99%, not more than 98% or not more than 97%, and particularly preferably not more than 95%. If the content of Ge+Te is too small, the amorphous state is likely to be unstable. Furthermore, the OTS characteristics are difficult to obtain. If the content of Ge+Te is too large, the OTS characteristics are difficult to obtain.

Si, Al, Ga, Sn, Bi, Cu, Ag, Zn, Y, In, Ca, and Mg are components that stabilize the amorphous states of the target for film deposition and the functional layer. Furthermore, these components are those that decrease the OFF current and thus can easily increase the ON/OFF current ratio. Therefore, the content of Si+Al+Ga+Sn+Bi+Cu+Ag+Zn+Y+In+Ca+Mg (the total content of Si, Al, Ga, Sn, Bi, Cu, Ag, Zn, Y, In, Ca, and Mg) is preferably 0% to 59% and particularly preferably 1% to 59%. More specifically, the content of Si+Al+Ga+Sn+Bi+Cu+Ag+Zn+Y+In+Ca+Mg is preferably not less than 0%, more preferably not less than 1%, particularly preferably not less than 2%, preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%. The content just described may be restated as follows: The target for film deposition contains at least one of components selected from among Si, Al, Ga, Sn, Bi, Cu, Ag, Zn, Y, In, Ca, and Mg. If the content of these components is too small, the above effects are difficult to obtain. If the content of these components is too large, the amorphous state is likely to be unstable. Furthermore, the OTS characteristics are difficult to obtain. The content of each component of Si, Al, Ga, Sn, Bi, Cu, Ag, Zn, Y, In, Ca, and Mg is preferably not less than 0%, more than 0%, not less than 0.1%, not less than 0.5% or not less than 1%, particularly preferably not less than 2%, preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%.

Among the above components, Ga and Ag are components that can easily decrease the OFF current and, therefore, contribute particularly to increasing the ON/OFF current ratio. Furthermore, these components are also those that particularly easily stabilize the amorphous state. The content of Ga+Ag (the total content of Ga and Ag) is preferably not less than 0%, more than 0%, not less than 0.1%, not less than 0.5%, not less than 1%, not less than 2% or not less than 3%, particularly preferably not less than 5%, preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%.

Particularly, from the viewpoint of decreasing the OFF current, Ga/(Ga+Ag) is preferably not less than 0.1, particularly preferably not less than 0.2, preferably not more than 1.2, more preferably less than 1.2, and particularly preferably not more than 1.1. Herein, Ga/(Ga+Ag) is a value of the content of Ga divided by the total content of Ga and Ag.

Sb is a component likely to make the amorphous state unstable at high temperatures. Therefore, the target for film deposition is preferably substantially free of Sb. Herein, “substantially free of” means that no amount of the relevant component is deliberately contained in the material, and is not intended to exclude even the incorporation thereof in impurity level. Objectively, this means that the content of the component is less than 0.1%. When it is desired to strictly reduce the incorporation of Sb, the content of Sb is preferably less than 0.05%, more preferably less than 0.01%, even more preferably less than 0.005%, still even more preferably less than 0.001%, and particularly preferably less than 0.0005%.

Se is a component that easily stabilizes the amorphous states of the target for film deposition and the functional layer. The content of Se is preferably not more than 58%, more preferably not more than 55%, particularly preferably not more than 50%, preferably not less than 0%, more preferably not less than 1%, even more preferably not less than 5%, still even more preferably not less than 10%, and particularly preferably not less than 20%. If the content of Se is too large, the amorphous state is likely to be unstable. Furthermore, Se is a toxic component. Therefore, from the viewpoint of reducing the burden on the environment, the content of Se is preferably not more than 40%, more preferably not more than 30%, even more preferably not more than 20%, and still even more preferably not more than 10%, and the target for film deposition is particularly preferably substantially free of Se.

As is a component that easily stabilizes the amorphous states of the target for film deposition and the functional layer. However, As is a toxic component. Therefore, from the viewpoint of reducing the burden on the environment, the content of As is preferably not more than 30%, not more than 25%, not more than 20%, not more than 10%, not more than 5% or not more than 3%, and the target for film deposition is particularly preferably substantially free of As.

The target for film deposition according to the present invention is preferably substantially free of Se and As. Thus, the burden on the environment can be more easily reduced.

S is a component that easily stabilizes the amorphous states of the target for film deposition and the functional layer. However, S is easily vaporized because of its low vapor pressure and, therefore, may contaminate the interior of a film deposition system due to heat applied during film deposition. For this reason, the content of S is preferably not more than 40%, more preferably not more than 30%, even more preferably not more than 20%, and still even more preferably not more than 10%, and the target for film deposition is particularly preferably substantially free of S.

B, C, N, F, Cl, Br, and I are components that easily stabilize the amorphous states of the target for film deposition and the functional layer. The content of B+C+N+F+Cl+Br+I (the total content of B, C, N, F, Cl, Br, and I) is preferably not more than 50%, not more than 45%, not more than 40%, not more than 35%, not more than 30%, not more than 25%, not more than 20%, not more than 15%, not more than 14%, not more than 12%, not more than 10%, not more than 8% or not more than 6%, and particularly preferably not more than 5%. If the content of B+C+N+F+Cl+Br+I is too large, the amorphous state is likely to be unstable. In addition, the weather resistance is likely to decrease. The content of each component of B, C, N, F, Cl, Br, and I is preferably not more than 50%, not more than 45%, not more than 40%, not more than 35%, not more than 30%, not more than 25%, not more than 20%, not more than 15%, not more than 14%, not more than 12%, not more than 10%, not more than 8% or not more than 6%, and particularly preferably not more than 5%.

The target for film deposition according to the present invention may contain P, Cr, Mn, Ti or Fe. The content of P+Cr+Mn+Ti+Fe (the total content of P, Cr, Mn, Ti, and Fe) is preferably not more than 10%, more preferably not more than 5%, even more preferably not more than 1%, still even more preferably less than 1%, and yet still even more preferably not more than 0.1%, and the target for film deposition is particularly preferably substantially free of these components. If the content of these components is too large, the amorphous state is likely to be unstable. The content of each component of P, Cr, Mn, Ti, and Fe is preferably not more than 10%, more preferably not more than 5%, even more preferably not more than 1%, still even more preferably less than 1%, and yet still even more preferably not more than 0.1%, and the target for film deposition is particularly preferably substantially free of the component. When it is desired to strictly reduce the incorporation of P, Cr, Mn, Ti, and Fe, the content of each of P, Cr, Mn, Ti, and Fe is preferably less than 0.05%, more preferably less than 0.01%, even more preferably less than 0.005%, still even more preferably less than 0.001%, and particularly preferably less than 0.0005%.

The target for film deposition according to the present invention is preferably substantially free of Cd, Tl, and Pb. Thus, the burden on the environment can be more easily reduced. When it is desired to strictly reduce the incorporation of Cd, Tl, and Pb, the content of each of Cd, Tl, and Pb is preferably less than 0.05%, more preferably less than 0.01%, even more preferably less than 0.005%, still even more preferably less than 0.001%, and particularly preferably less than 0.0005%.

The components of the target for film deposition and the later-described functional layer can be evaluated using energy dispersive X-ray spectroscopy (EDX), an electron probe microanalyzer (EPMA), X-ray fluorescence analysis (XRF), RBS (Rutherford backscattering spectroscopic analysis) or so on. The evaluation by EDX may be made with an analyzer TEM-EDX or SEM-EDX attached to a transmission electron microscope (TEM) or a scanning electron microscope (SEM) respectively.

### <Production Method of Functional Layer>

In a certain wide aspect, in a method for producing a functional layer according to the present invention, the target for film deposition is preferably made of a bulk chalcogenide glass containing, in terms of atomic %, 0.1% to 50% Ge and 40% to 90% Te, and a functional layer containing, in terms of atomic %, 0.1% to 50% Ge and 40% to 90% Te is preferably produced. The functional layer is preferably a variable-resistance layer or a phase-change layer.

The thickness of the functional layer is preferably 1 to 300 nm. More specifically, the thickness of the functional layer is preferably not less than 1 nm, more preferably not less than 2 nm, even more preferably not less than 5 nm, still even more preferably not less than 10 nm, yet still even more preferably not less than 30 nm, particularly preferably more than 50 nm, preferably not more than 300 nm, more preferably not more than 200 nm, and particularly preferably not more than 100 nm. If the thickness is too small, the current value (OFF current) in a high-resistance state tends to be high. If the thickness is too large, the threshold voltage is likely to be large.

The film deposition method is preferably a physical vapor deposition method because the composition and the film thickness can be easily controlled. For example, the sputtering process, vacuum evaporation or ion plating is preferably used and the sputtering process is particularly preferably used. In this case, the target for film deposition according to the present invention can be used as a sputtering target. However, the film deposition method is not limited to the physical vapor deposition method and may be a CVD (chemical vapor deposition) method, an ALD (atomic layer deposition) method or so on.

For example, film deposition by the sputtering process can be done by setting the substrate temperature at 15° C. to 400° C., the flow rate of inert gas, such as argon gas, as the sputtering gas at 2 sccm to 1000 sccm, the flow rate of oxygen gas at 0 sccm to 400 sccm, and the applied voltage at 1 W to 1 kW.

From the viewpoint of fine-adjusting the film deposition conditions for each component, in the method for producing a functional layer according to the present invention, the functional layer may be produced using a plurality of targets for film deposition. For example, in the method for producing a functional layer according to the present invention, a second target for film deposition may be further provided or three or more targets for film deposition may be used. More specifically, for example, a plurality of targets for film deposition made of a bulk chalcogenide glass may be used. Alternatively, a target for film deposition made of a bulk chalcogenide glass and a metallic target may be used in combination. Still alternatively, a target for film deposition made of a bulk chalcogenide glass and an alloy target may be used in combination. However, the target for film deposition is not limited to a structure made of a bulk chalcogenide glass and various kinds of targets for film deposition described previously can be used in combination. Alternatively, a plurality of targets for film depositions each containing the same constituents may be used in combination. However, from the viewpoint of simplifying the film deposition process, it is preferred to use a single target for film deposition.

In the method for producing a functional layer according to the present invention, a target for film deposition free of chalcogenide glass may be used. For example, in a method for producing a functional layer using a plurality of targets for film deposition, it is preferred that the targets for film deposition include a target for film deposition made of a Ga alloy or a Ga compound and the functional layer is a variable-resistance layer or a phase-change layer each of which contains, in terms of atomic %, 0.1% to 50% Ge, 0.1% to 50% Ga, and 40% to 90% Te. In this embodiment, at least one of the targets for film deposition is made of a Ga alloy or a Ga compound. Metal Ga is easily melted because of its melting point as low as approximately 30° C. and is therefore difficult to handle. To cope with this, in this embodiment, not a target for film deposition of elemental Ga metal, but a target for film deposition with Ga alloyed or compounded with another substance is used, which increases the melting point of the target for film deposition and makes the target easily handleable. Examples of the Ga alloy that can be used include a Ga—Te alloy, a Ga—In alloy, a Ga—Sn alloy, a Ga—Ge alloy, and a Ga—In—Sn alloy. The Ga alloy to be used is not limited to such alloys as just described and may contain such components as Si, Al, Bi, Cu, Ag, Zn, Y, Ca and/or Mg. Examples of the Ga compound that can be used include a Ga oxide, a Ga hydroxide, a Ga nitride, and a Ga intermetallic compound.

For example, in the method for producing a functional layer according to the present invention, a target for film deposition made of a Ga alloy or a Ga compound, a Te metal target, and a Ge metal target can be used in combination. For example, in the case of using a Ga—Te alloy as the Ga alloy or the Ga compound, a target for film deposition made of a Ga—Te alloy and a Ge metal target can be used in combination. For example, in the case of using a Ga—Ge alloy as the Ga alloy or the Ga compound, a target for film deposition made of a Ga—Ge alloy and a Te metal target can be used in combination.

The functional layer preferably contains, in terms of atomic %, 0.1% to 50% Ge and 40% to 90% Te and more preferably contains, in terms of atomic %, 0.1% to 50% Ge, 0.1% to 50% Ga, and 40% to 90% Te. The respective detailed contents of the components are as follows.

Ge is a component that stabilizes the amorphous state of the functional layer. The content of Ge is preferably 0.1% to 50%. More specifically, the content of Ge is preferably not less than 0.1%, not less than 1%, not less than 3%, not less than 5%, not less than 7%, not less than 10%, not less than 11% or not less than 13%, particularly preferably not less than 15%, preferably not more than 50%, not more than 40% or not more than 30%, and particularly preferably not more than 20%. If the content of Ge is too small, the amorphous state is likely to be unstable. If the content of Ge is too large, the OTS characteristics are difficult to obtain. In addition, the production cost is likely to increase.

Te is an essential constituent of the functional layer. The content of Te is preferably 40% to 90%. More specifically, the content of Te is preferably not less than 40%, not less than 42%, not less than 47%, not less than 50%, more than 50%, not less than 51%, not less than 53%, not less than 55%, not less than 60%, not less than 61%, not less than 65%, not less than 67% or not less than 70%, particularly preferably not less than 71%, preferably not more than 90%, not more than 89%, not more than 85% or not more than 82.5%, and particularly preferably not more than 80%. If the content of Te is too small, the amorphous state is likely to be unstable. Furthermore, the OTS characteristics are difficult to obtain. If the content of Te is too large, the amorphous state is likely to be unstable. Furthermore, the OFF current value is likely to be large and the OTS characteristics are difficult to obtain.

The content of Ge+Te (the total content of Ge and Te) is preferably not less than 41%, not less than 45%, not less than 50%, not less than 60%, not less than 65%, not less than 70% or not less than 75%, particularly preferably not less than 80%, preferably not more than 99%, not more than 98% or not more than 97%, and particularly preferably not more than 95%. If the content of Ge+Te is too small, the amorphous state is likely to be unstable. Furthermore, the OTS characteristics are difficult to obtain. If the content of Ge+Te is too large, the OTS characteristics are difficult to obtain.

Si, Al, Ga, Sn, Bi, Cu, Ag, Zn, Y, In, Ca, and Mg are components that stabilize the amorphous state of the functional layer. Furthermore, these components are those that decrease the OFF current and thus can easily increase the ON/OFF current ratio. Therefore, the content of Si+Al+Ga+Sn+Bi+Cu+Ag+Zn+Y+In+Ca+Mg (the total content of Si, Al, Ga, Sn, Bi, Cu, Ag, Zn, Y, In, Ca, and Mg) is preferably 0% to 59% and particularly preferably 1% to 59%. More specifically, the content of Si+Al+Ga+Sn+Bi+Cu+Ag+Zn+Y+In+Ca+Mg is preferably not less than 0%, more preferably not less than 1%, particularly preferably not less than 2%, preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%. The content just described may be restated as follows: The functional layer contains at least one of components selected from among Si, Al, Ga, Sn, Bi, Cu, Ag, Zn, Y, In, Ca, and Mg. If the content of these components is too small, the above effects are difficult to obtain. If the content of these components is too large, the amorphous state is likely to be unstable. Furthermore, the OTS characteristics are difficult to obtain. The content of each component of Si, Al, Ga, Sn, Bi, Cu, Ag, Zn, Y, In, Ca, and Mg is preferably not less than 0%, more than 0%, not less than 0.1%, not less than 0.5% or not less than 1%, particularly preferably not less than 2%, preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%.

Among the above components, Ga and Ag are components that can easily decrease the OFF current and, therefore, contribute particularly to increasing the ON/OFF current ratio. Furthermore, these components are also those that particularly easily stabilize the amorphous state. The content of Ga+Ag (the total content of Ga and Ag) is preferably not less than 0%, more than 0%, not less than 0.1%, not less than 0.5%, not less than 1%, not less than 2% or not less than 3%, particularly preferably not less than 5%, preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%.

Particularly, from the viewpoint of decreasing the OFF current, Ga/(Ga+Ag) is preferably not less than 0.1, particularly preferably not less than 0.2, preferably not more than 1.2, more preferably less than 1.2, and particularly preferably not more than 1.1. Herein, Ga/(Ga+Ag) is a value of the content of Ga divided by the total content of Ga and Ag.

Sb is a component likely to make the amorphous state of the functional layer unstable at high temperatures. Therefore, the functional layer is preferably substantially free of Sb. When it is desired to strictly reduce the incorporation of Sb, the content of Sb is preferably less than 0.05%, more preferably less than 0.01%, even more preferably less than 0.005%, still even more preferably less than 0.001%, and particularly preferably less than 0.0005%.

Se is a component that easily stabilizes the amorphous state of the functional layer. The content of Se is preferably not more than 58%, more preferably not more than 55%, particularly preferably not more than 50%, preferably not less than 0%, more preferably not less than 1%, even more preferably not less than 5%, still even more preferably not less than 10%, and particularly preferably not less than 20%. If the content of Se is too large, the amorphous state is likely to be unstable. Furthermore, Se is a toxic component. Therefore, from the viewpoint of reducing the burden on the environment, the content of Se is preferably not more than 40%, more preferably not more than 30%, even more preferably not more than 20%, and still even more preferably not more than 10%, and the functional layer is particularly preferably substantially free of Se.

As is a component that easily stabilizes the amorphous state of the functional layer. However, As is a toxic component. Therefore, from the viewpoint of reducing the burden on the environment, the content of As is preferably not more than 30%, not more than 25%, not more than 20%, not more than 10%, not more than 5% or not more than 3%, and the functional layer is particularly preferably substantially free of As.

The functional layer is preferably substantially free of Se and As. Thus, the burden on the environment can be more easily reduced.

S is a component that easily stabilizes the amorphous state of the functional layer. However, S is easily vaporized because of its low vapor pressure and, therefore, may contaminate the interior of a film deposition system due to heat applied during film deposition. For this reason, the content of S is preferably not more than 40%, more preferably not more than 30%, even more preferably not more than 20%, and still even more preferably not more than 10%, and the functional layer is particularly preferably substantially free of S.

B, C, N, F, Cl, Br, and I are components that easily stabilize the amorphous state of the functional layer. The content of B+C+N+F+Cl+Br+I (the total content of B, C, N, F, Cl, Br, and I) is preferably not more than 50%, not more than 45%, not more than 40%, not more than 35%, not more than 30%, not more than 25%, not more than 20%, not more than 15%, not more than 14%, not more than 12%, not more than 10%, not more than 8% or not more than 6%, and particularly preferably not more than 5%. If the content of B+C+N+F+Cl+Br+I is too large, the amorphous state is likely to be unstable. In addition, the weather resistance is likely to decrease. The content of each component of B, C, N, F, Cl, Br, and I is preferably not more than 50%, not more than 45%, not more than 40%, not more than 35%, not more than 30%, not more than 25%, not more than 20%, not more than 15%, not more than 14%, not more than 12%, not more than 10%, not more than 8% or not more than 6%, and particularly preferably not more than 5%.

The functional layer may contain P, Cr, Mn, Ti or Fe. The content of P+Cr+Mn+Ti+Fe (the total content of P, Cr, Mn, Ti, and Fe) is preferably not more than 10%, more preferably not more than 5%, even more preferably not more than 1%, still even more preferably less than 1%, and yet still even more preferably not more than 0.1%, and the functional layer is particularly preferably substantially free of these components. If the content of these components is too large, the amorphous state is likely to be unstable. The content of each component of P, Cr, Mn, Ti, and Fe is preferably not more than 10%, more preferably not more than 5%, even more preferably not more than 1%, still even more preferably less than 1%, and yet still even more preferably not more than 0.1%, and the functional layer is particularly preferably substantially free of the component. When it is desired to strictly reduce the incorporation of P, Cr, Mn, Ti, and Fe, the content of each of P, Cr, Mn, Ti, and Fe is preferably less than 0.05%, more preferably less than 0.01%, even more preferably less than 0.005%, still even more preferably less than 0.001%, and particularly preferably less than 0.0005%.

The functional layer is preferably substantially free of Cd, Tl, and Pb. Thus, the burden on the environment can be more easily reduced. When it is desired to strictly reduce the incorporation of Cd, Tl, and Pb, the content of each of Cd, Tl, and Pb is preferably less than 0.05%, more preferably less than 0.01%, even more preferably less than 0.005%, still even more preferably less than 0.001%, and particularly preferably less than 0.0005%.

As thus far described, the target for film deposition according to the present invention can be used suitably for production of the functional layer. The functional layer can be suitably used as a variable-resistance layer or a phase-change layer. Therefore, the target for film deposition according to the present invention can be used suitably for production of a memory element for use in a resistance-variable memory device or a phase-change memory device or production of a switch element for use in various memory devices.

### <Switch Element>

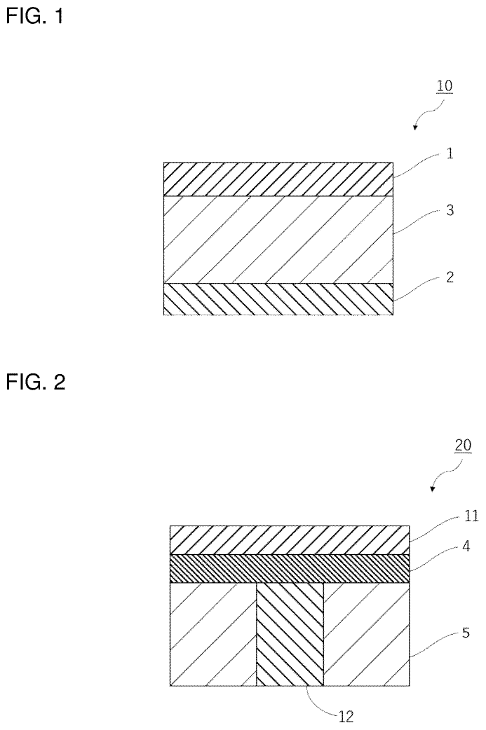

FIG. 1 is a schematic cross-sectional view of a switch element according to an embodiment of the present invention. A switch element 10 includes a first electrode 1, a second electrode 2, and a functional layer disposed on a principal surface of the first electrode 1. In this embodiment, the functional layer is a switch layer 3. The second electrode 2 is disposed opposite to the first electrode 1. The switch layer 3 is disposed between the first electrode 1 and the second electrode 2. In other words, the switch element 10 according to this embodiment includes the switch layer 3 and the first electrode 1 disposed on the switch layer 3. In still other words, the switch element 10 according to this embodiment includes the second electrode 2 opposed to the first electrode 1 with the switch layer 3 in between.

The switch element 10 can be used in a cross-point memory device or a BiCS (bit-cost scalable) memory device which will be described later. In the case of a BiCS memory device, the switch element 10 preferably has a structure in which the first electrode 1 is disposed on the outer periphery of the switch layer 3 and the second electrode 2 is disposed on the inner periphery of the switch layer 3.

An inorganic material may be used for the first electrode 1 and the second electrode 2. A metallic material or a ceramic material is preferably used as the inorganic material. The metallic material is, for example, preferably at least one selected from among tungsten, titanium, copper and platinum. The ceramic material is, for example, preferably tungsten nitride or titanium nitride.

The thicknesses of the first electrode 1 and the second electrode 2 can be appropriately designed. For example, the thickness of each of the first electrode 1 and the second electrode 2 is preferably not more than 200 nm, more preferably not more than 100 nm, even more preferably not more than 80 nm, still even more preferably not more than 60 nm, and particularly preferably not more than 50 nm. Smaller thickness of each of the first electrode 1 and the second electrode 2 is more advantageous to increasing the capacity of a memory device. The lower limit of the thickness of each of the first electrode 1 and the second electrode 2 is not particularly limited, but is preferably not less than 1 nm and particularly preferably not less than 2 nm.

The switch layer 3 is a variable-resistance layer and exhibits OTS characteristics. The switch layer 3 is disposed in contact with at least one of the electrodes. In other words, the switch layer 3 is preferably disposed on the first electrode 1. In still other words, the first electrode 1 is preferably disposed on the switch layer 3.

The thickness of the switch layer 3 can be appropriately designed according to a desired threshold voltage. The thickness of the switch layer 3 is, for example, preferably not more than 300 nm, more preferably not more than 200 nm, and particularly preferably not more than 100 nm. If the thickness of the switch layer 3 is too large, the threshold voltage is likely to be excessively large. The lower limit of the thickness of the switch layer 3 is, for example, preferably not less than 1 nm, more preferably not less than 2 nm, even more preferably not less than 5 nm, still even more preferably not less than 10 nm, yet still even more preferably not less than 30 nm, and particularly preferably more than 50 nm.

The ON/OFF current ratio of the switch element 10 is preferably not less than 1×10⁴, more preferably not less than 1×10⁵, and particularly preferably not less than 1×10⁶. When the ON/OFF current ratio meets the above values, the switch element 10 has excellent OTS characteristics.

### <Memory Element>

FIG. 2 is a schematic cross-sectional view of a memory element according to a first embodiment of the present invention. A memory element 20 includes a first electrode 11, a second electrode 12, a memory layer 4, and an insulator 5. The memory layer 4 is a functional layer formed using the target for film deposition according to the present invention. The first electrode 11 is formed on a top surface of the memory layer 4. The second electrode 12 is formed on an underside surface of the memory layer 4 and disposed opposite to the first electrode 11. The periphery of the second electrode 12 is covered with the insulator 5. In this embodiment, the memory layer 4 is disposed between the first electrode 11 and the second electrode 12.

An inorganic material may be used for the first electrode 11 and the second electrode 12. A metallic material or a ceramic material may be used as the inorganic material. The metallic material is, for example, preferably at least one selected from among tungsten, titanium, copper and platinum. The ceramic material is, for example, preferably tungsten nitride or titanium nitride.

The thicknesses of the first electrode 11 and the second electrode 12 can be appropriately designed. For example, the thickness of each of the first electrode 11 and the second electrode 12 is preferably not more than 200 nm, more preferably not more than 100 nm, even more preferably not more than 80 nm, still even more preferably not more than 60 nm, and particularly preferably not more than 50 nm. Smaller thickness of each of the first electrode 11 and the second electrode 12 is more advantageous to increasing the capacity of a memory device. The lower limit of the thickness of each of the first electrode 11 and the second electrode 12 is not particularly limited, but is preferably not less than 1 nm and particularly preferably not less than 2 nm.

The memory layer 4 has a different structure depending on the type of the memory. For example, in the case of a phase-change memory, the memory layer 4 is a phase-change layer. When a high voltage is applied to the memory layer 4, the memory layer 4 changes the phase to a crystalline or amorphous state and, thus, can record information therein. For example, when a high voltage is applied to the memory layer 4 in a crystalline state and the memory layer 4 is rapidly heated and cooled, the memory layer 4 changes to an amorphous state (a first phase change). Furthermore, when a lower voltage than in the case of the first phase change is applied to the memory layer 4 in an amorphous state and the memory layer 4 is gently heated and cooled, the memory layer 4 changes to a crystalline state (a second phase change). By allocating 0 and 1 to an amorphous state (high-resistance state) and a crystalline state (low-resistance state), respectively, information can be recorded.

The memory layer 4 preferably precipitates, in a crystalline state, at least one type of crystals selected from among Ge₂Sb₂Te₅, GeTe₄, GeTe, Te, and GazTe₃. Particularly, GeTe₄ crystals can reduce the power consumption of the memory element because the amount of energy necessary for phase transition from a crystalline state to an amorphous state is small.

### <Memory Device>

### First Embodiment

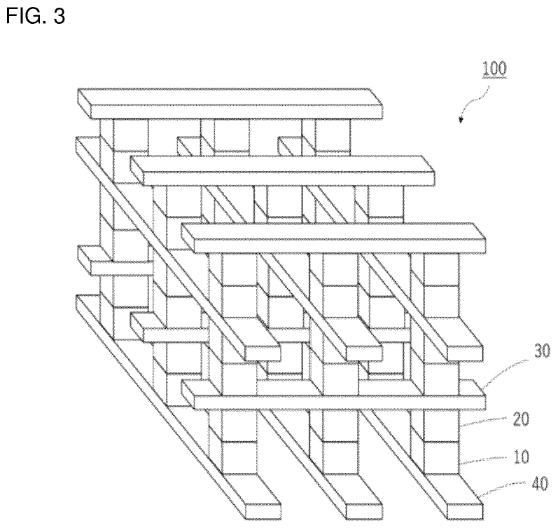

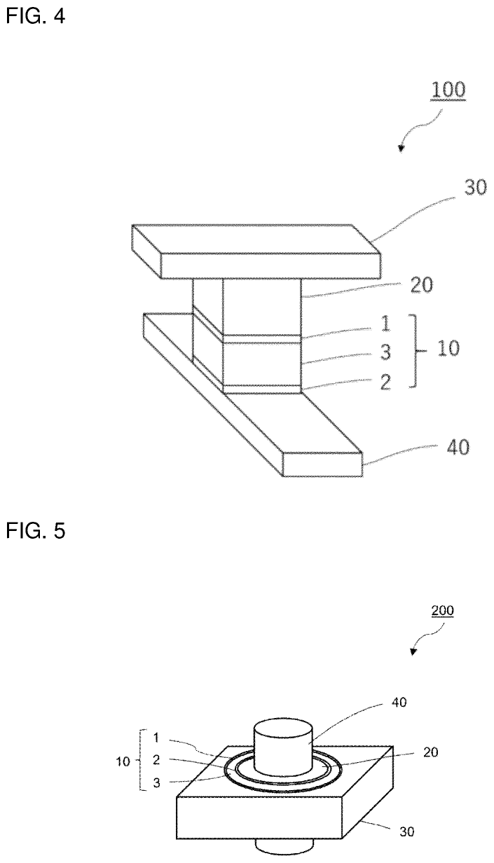

A memory device according to this embodiment includes a switch element and a memory element. FIGS. 3 and 4 are schematic stereograms of a memory device according to a first embodiment of the present invention. FIG. 4 is a partly enlarged view of the schematic stereogram of FIG. 3. As shown in FIGS. 3 and 4, a memory device 100 includes switch elements 10, memory elements 20, word lines 30, and bit lines 40. The bit line 40 is orthogonal to the word line 30 in plan view. The switch elements 10 and the memory elements 20 are disposed at the intersections between the word lines 30 and the bit lines 40 in plan view. Accordingly, the memory device 100 is a cross-point memory device.

FIG. 5 is a schematic stereogram of a modification of the memory device according to the first embodiment of the present invention. A memory device 200 includes switch elements 10, memory elements 20, word lines 30, and bit lines 40. A bit line 40 is disposed through a through hole provided in a word line 30. Furthermore, a memory element 20 and a switch element 10 are disposed on the outer periphery of the bit line 40. The switch element 10 has a structure in which a first electrode 1 is disposed on the outer periphery of a switch layer 3 and a second electrode 2 is disposed on the inner periphery of the switch layer 3 and opposed to the first electrode 1 with the switch layer 3 in between. Accordingly, the memory device 200 according to this embodiment is a BiCS memory device. As thus far described, the memory device according to the present invention is not limited to a cross-point memory device and may be various types of memory device.

As the memory element 20, any type of memory element may be used, including a variable-resistance memory element, a magnetoresistive memory element, a phase-change memory element, and a ferroelectric memory element. Hereinafter, a description will be given of preferred forms of each type of memory element.

The variable-resistance memory element includes a variable-resistance layer. More specifically, the variable-resistance memory element preferably includes a laminate in which a variable-resistance layer is sandwiched between a first electrode and a second electrode. The variable-resistance layer is preferably made of a metal oxide material, a metal nitride material or a chalcogenide material. The metal oxide material is, for example, preferably at least one selected from among NiOₓ, NbOₓ, TiOₓ, TaOₓ, HfOₓ, ZrOₓ, MoOₓ, WOₓ, and Pr₁₋ₓCaₓMnO₃ (PCMO). The metal nitride material is, for example, preferably at least one selected from among SiNₓ, AlNₓ, ZrNₓ, NiNₓ, CuNₓ, and CrNₓ. The chalcogenide material may be at least one selected from among Ge—Te, Sb—Te, Ge—Sb—Te, Si—Sb—Te, Ge—Ga—Te, In—Sb—Te, Ge—Se—As, and Ge—Se—As—Te. Alternatively, the variable-resistance layer may be formed of carbon nanotubes.

The magnetoresistive memory element includes a laminate (a TMR element) in which an insulator layer is sandwiched between ferromagnetic layers. The insulator layer is made of an insulating material and is, for example, preferably made of at least one selected from among MgO, Cao, SrO, and Al₂O₃. The thickness of the insulator layer is preferably 0.1 nm to 3 nm. The ferromagnetic layer is made of a ferromagnetic material and is, for example, preferably made of at least one selected from among CoFeB, FeB, NiFe, MnIr, Fe, CoPt, CoNi, Co, Ni, Pt, Ni, and Mn.

The ferroelectric memory element includes a ferroelectric layer. More specifically, the ferroelectric memory element preferably includes a laminate in which a ferroelectric layer is sandwiched between a first electrode and a second electrode. The ferroelectric layer is preferably made of a ferroelectric material containing hafnium oxide and, for example, preferably made of hafnium oxide doped with at least one selected from among Si, Zr, Ge, Gd, La, Y, and Yb. Alternatively, the ferroelectric layer may be made of at least one selected from among lead zirconate titanate (PZT), strontium bismuth tantalate (SBT), and bismuth ferrite (BFO).

The phase-change memory element includes a memory layer formed of a phase-change material. More specifically, the phase-change memory element preferably includes a laminate in which a phase-change layer is sandwiched between a first electrode and a second electrode. The phase-change layer is preferably made of a chalcogenide material. The chalcogenide material is, for example, preferably at least one selected from among Ge—Te, Sb—Te, Ge—Sb—Te, Si—Sb—Te, Ge—Ga—Te, In—Sb—Te, Cu—Ge—Te, Cr—Ge—Te, Mn—Te, Ge—Se—As, and Ge—Se—As—Te.

In the above memory element, an inorganic material may be used for the first electrode 1 and the second electrode 2. A metallic material or a ceramic material is preferably used as the inorganic material. The metallic material is, for example, preferably at least one selected from among tungsten, titanium, copper and platinum. The ceramic material is, for example, preferably tungsten nitride or titanium nitride.

### Second Embodiment

The memory device is not limited to the structure that includes a switch layer and a memory element separately. For example, the memory device according to this embodiment includes a switch element only. In this case, the switch element functions as a switch element and a memory element.

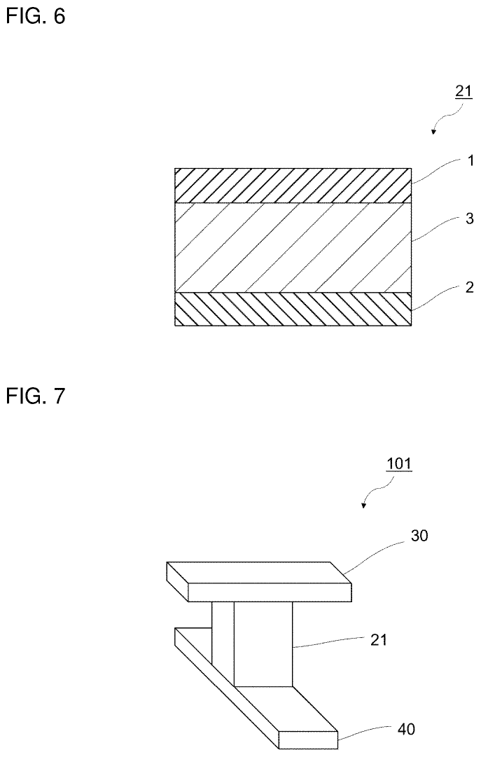

FIG. 6 is a schematic cross-sectional view of a memory element according to a second embodiment of the present invention. As shown in FIG. 6, a switch element 21 includes a first electrode 1, a second electrode 2, and a functional layer disposed on a principal surface of the first electrode 1. In this embodiment, the functional layer is a switch layer 3. The second electrode 2 is disposed opposite to the first electrode 1. The switch layer 3 is disposed between the first electrode 1 and the second electrode 2. In other words, the switch element 10 according to this embodiment includes the switch layer 3 and the first electrode 1 disposed on the switch layer 3. In still other words, the switch element 10 according to this embodiment includes the second electrode 2 opposed to the first electrode 1 with the switch layer 3 in between. The switch element 21 functions as a switch element and a memory element.

FIG. 7 is a schematic stereogram of a memory device according to a second embodiment of the present invention. As shown in FIG. 7, a memory device 101 includes a switch element 21, a word line 30, and a bit line 40. The bit line 40 is orthogonal to the word line 30 in plan view. The switch element 21 is disposed at the intersection between the word line 30 and the bit line 40 in plan view. Accordingly, the memory device 101 according to this embodiment is a so-called cross-point memory device.

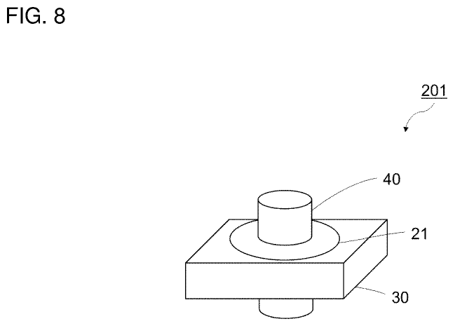

FIG. 8 is a schematic stereogram of a modification of the memory device according to the second embodiment of the present invention. As shown in FIG. 8, a memory device 201 includes a memory element 21, a word line 30, and a bit line 40. The bit line 40 is disposed through a through hole provided in the word line 30. The memory element 21 is disposed on the outer periphery of the bit line 40. Accordingly, the memory device 201 according to this embodiment is a so-called BiCS memory device. As thus far described, also in this embodiment, the memory device is not limited to a cross-point memory device and may be various types of memory device.

### EXAMPLES

Hereinafter, the present invention will be described with reference to examples, but the present invention is not limited to these examples.

Tables 1 to 7 show Examples 1 to 51 (Ex. 1 to Ex. 51) of the present invention and Comparative Example 1 (CEx. 1).

TABLE 1

| atomic % | Ex. 1 | Ex. 2 | Ex. 3 | Ex. 4 | Ex. 5 | Ex. 6 | Ex. 7 | Ex. 8 |
|---|---|---|---|---|---|---|---|---|
| Ge | 18 | 12.9 | 15.4 | 14.6 | 14.2 | 15.4 | 14.6 | 14.2 |
| Ga | 5 | 5 | 2.5 | 7.5 | 10 | 5.1 | 4.9 | 4.7 |
| Ag | 5 | 5 | 5.1 | 4.9 | 4.7 | 2.5 | 7.5 | 10 |
| Te | 72 | 77.1 | 77 | 73 | 71.1 | 77 | 73 | 71.1 |
| Si | 0 | 0 | 0 | 0 | 0 | 0 | 0 | 0 |
| Ge + Te | 90 | 90 | 92.4 | 87.6 | 85.3 | 92.4 | 87.6 | 85.3 |
| Ga + Ag | 10 | 10 | 7.6 | 12.4 | 14.7 | 7.6 | 12.4 | 14.7 |
| Crystallization | 274 | 242 | 231 | 268 | 289 | 238 | 257 | 281 |
| Temperature | | | | | | | | |
| Tx (° C.) | | | | | | | | |

TABLE 2

| | Ex. | Ex. | Ex. | Ex. | Ex. | Ex. | Ex. | Ex. |
|---|---|---|---|---|---|---|---|---|
| atomic % | 9 | 10 | 11 | 12 | 13 | 14 | 15 | 16 |
| Ge | 13.3 | 15.8 | 12.2 | 15 | 15 | 25 | 15 | 15 |
| Ga | 10 | 2.5 | 10 | 15 | 25 | 15 | 15 | 5 |
| Ag | 10 | 2.5 | 4.7 | 22.5 | 12.5 | 12.5 | 12.5 | 22.5 |
| Te | 66.7 | 79.2 | 73 | 47.5 | 47.5 | 47.5 | 57.5 | 57.5 |
| Si | 0 | 0 | 0 | 0 | 0 | 0 | 0 | 0 |
| Ge + Te | 80 | 95 | 85.2 | 62.5 | 62.5 | 72.5 | 72.5 | 72.5 |
| Ga + Ag | 20 | 5 | 14.7 | 37.5 | 37.5 | 27.5 | 27.5 | 27.5 |
| Crystallization | 289 | 223 | 267 | 189 | 172 | 168 | 198 | 202 |
| Temperature | | | | | | | | |
| Tx (° C.) | | | | | | | | |

TABLE 3

| | Ex. | Ex. | Ex. | Ex. | Ex. | Ex. | Ex. | Ex. |
|---|---|---|---|---|---|---|---|---|
| atomic % | 17 | 18 | 19 | 20 | 21 | 22 | 23 | 24 |
| Ge | 15 | 5 | 35 | 5 | 27.5 | 15.4 | 15 | 15 |
| Ga | 15 | 15 | 15 | 15 | 15 | 7.7 | 15 | 25 |
| Ag | 2.5 | 22.5 | 2.5 | 12.5 | 0 | 0 | 12.5 | 2.5 |
| Te | 67.5 | 57.5 | 47.5 | 67.5 | 57.5 | 76.9 | 57.5 | 57.5 |
| Si | 0 | 0 | 0 | 0 | 0 | 0 | 0 | 0 |
| Ge + Te | 82.5 | 62.5 | 82.5 | 72.5 | 85 | 92.3 | 72.5 | 72.5 |
| Ga + Ag | 17.5 | 37.5 | 17.5 | 27.5 | 15 | 7.7 | 27.5 | 27.5 |
| Crystallization | 210 | 207 | 202 | 193 | 200 | 245 | 213 | 224 |
| Temperature | | | | | | | | |
| Tx (° C.) | | | | | | | | |

TABLE 4

| | Ex. | Ex. | Ex. | Ex. | Ex. | Ex. | Ex. | Ex. |
|---|---|---|---|---|---|---|---|---|
| atomic % | 25 | 26 | 27 | 28 | 29 | 30 | 31 | 32 |
| Ge | 12.9 | 10.4 | 15.85 | 17.1 | 14.6 | 14.6 | 21.1 | 15 |
| Ga | 10.2 | 12.7 | 8.55 | 9.8 | 9.8 | 12.3 | 5 | 7.5 |
| Ag | 0 | 0 | 0 | 0 | 0 | 0 | 0 | 0 |
| Te | 71.9 | 71.9 | 70.6 | 68.1 | 70.6 | 68.1 | 52.8 | 75 |
| Si | 5 | 5 | 5 | 5 | 5 | 5 | 21.1 | 2.5 |
| Ge + Te | 84.8 | 82.3 | 86.45 | 85.2 | 85.2 | 82.7 | 73.9 | 90 |
| Ga + Ag | 10.2 | 12.7 | 8.55 | 9.8 | 9.8 | 12.3 | 5 | 7.5 |
| Crystal- | 267 | 278 | 275.1 | 284 | 296.6 | 294.6 | 314 | 288 |
| lization | | | | | | | | |
| Temperature | | | | | | | | |
| Tx (° C.) | | | | | | | | |

TABLE 5

| | Ex. | Ex. | Ex. | Ex. | Ex. | Ex. | Ex. | Ex. |
|---|---|---|---|---|---|---|---|---|
| atomic % | 33 | 34 | 35 | 36 | 37 | 38 | 39 | 40 |
| Ge | 14.6 | 14.3 | 13.9 | 12.5 | 5 | 14.25 | 15 | 14.25 |
| Ga | 7.3 | 7.1 | 6.9 | 5 | 10 | 4.75 | 15 | 4.75 |
| Ag | 0 | 0 | 0 | 7.5 | 2.5 | 4.75 | 12.5 | 4.75 |
| Te | 73.1 | 71.1 | 69.2 | 75 | 72.5 | 71.25 | 57.5 | 71.25 |
| Si | 5 | 7.5 | 10 | 0 | 10 | 5 | 0 | 5 |
| Ge + Te | 87.7 | 85.4 | 83.1 | 87.5 | 77.5 | 85.5 | 72.5 | 85.5 |
| Ga + Ag | 7.3 | 7.1 | 6.9 | 12.5 | 12.5 | 9.5 | 27.5 | 9.5 |
| Crystal- | 292.3 | 302 | 318 | 257 | 279 | 281.4 | 194 | 286 |
| lization | | | | | | | | |
| Temper- | | | | | | | | |
| ature | | | | | | | | |
| Tx (° C.) | | | | | | | | |

TABLE 6

| | Ex. | Ex. | Ex. | Ex. | Ex. | Ex. | Ex. | Ex. |
|---|---|---|---|---|---|---|---|---|
| atomic % | 41 | 42 | 43 | 44 | 45 | 46 | 47 | 48 |
| Ge | 14.6 | 25 | 2.5 | 1.25 | 5.1 | 2.6 | 7.5 | 2.5 |
| Ga | 7.3 | 15 | 10 | 12.5 | 10.2 | 12.8 | 12.5 | 12.5 |
| Ag | 0 | 2.5 | 2.5 | 2.5 | 0 | 0 | 2.5 | 2.5 |
| Te | 73.1 | 57.5 | 72.5 | 71.25 | 74.4 | 74.3 | 72.5 | 72.5 |
| Si | 5 | 0 | 12.5 | 12.5 | 10.3 | 10.3 | 5 | 10 |
| Ge + Te | 87.7 | 82.5 | 75 | 72.5 | 79.5 | 76.9 | 80 | 75 |
| Ga + Ag | 7.3 | 17.5 | 12.5 | 15 | 10.2 | 12.8 | 15 | 15 |
| Crystal- | 307 | 216 | 346.8 | 337.4 | 333.1 | 331 | 314.4 | 327.8 |
| lization | | | | | | | | |
| Temperature | | | | | | | | |
| Tx (° C.) | | | | | | | | |

TABLE 7

| atomic % | Ex. 49 | Ex. 50 | Ex. 51 | CEx. 1 |
|---|---|---|---|---|
| Ge | 10 | 5 | 30 | 22 |
| Ga | 10 | 10 | 3.5 | 0 |
| Ag | 2.5 | 2.5 | 3.5 | 0 |
| Te | 72.5 | 72.5 | 63 | 56 |
| Si | 5 | 10 | 0 | 0 |
| Sb | 0 | 0 | 0 | 22 |
| Ge + Te | 82.5 | 77.5 | 93 | 78 |
| Ga + Ag | 12.5 | 12.5 | 7 | 0 |
| Crystallization | 313.5 | 334.7 | 176 | 160 |
| Temperature | | | | |
| Tx (° C.) | | | | |

Each sample was produced in the following manner. First, a quartz glass ampule was evacuated while being heated, and raw materials were then formulated to have the relevant composition shown in Tables 1 to 7 and put into the quartz glass ampule. Next, the quartz glass ampule was sealed with an oxygen burner. Next, the sealed quartz glass ampule was placed into a melting furnace and the temperature of the melting furnace was raised to 650° C. to 1000° C. at a rate of 10° C./h to 40° C./h and then held for 6 hours to 12 hours. During the holding time, the quartz glass ampule was turned upside down to stir the melt. Finally, the quartz glass ampule was taken out of the melting furnace and rapidly cooled to room temperature, thus obtaining a bulk chalcogenide glass. The bulk chalcogenide glass was cut and polished, thus obtaining a disc-shaped target for film deposition with a diameter of 50.8 mm and a thickness of 3 mm. Examples 12 to 15, 39, and 51 contained a crystalline phase. Precipitated crystals were Ge crystals, Te crystals, GeTe₄, GeTe, Ga₂Te₃ or so on.

The obtained samples were measured in terms of crystallization temperature Tx by DTA.

As shown in Tables 1 to 7, the targets for film deposition in Examples 1 to 51 exhibited a higher crystallization temperature Tx compared to Comparative Example 1. Furthermore, as a result of production of thin films with a thickness of 150 nm using the targets for film deposition in Examples 1 and 42, the components of the thin film obtained using the target for film deposition in Example 1 were, in terms of atomic %, 17.7% Ge, 6.3% Ga, 3.8% Ag, and 72.2% Te. The components of the thin film obtained using the target for film deposition in Example 42 were, in terms of atomic %, 22.2% Ge, 16.8% Ga, 2.7% Ag, and 58.3% Te. The film deposition was conducted by Ar sputtering under a reduced-pressure atmosphere. In doing so, the substrate temperature was set at 15° C. to 400° C., the flow rate of Ar gas was set at 2 sccm to 1000 sccm, the flow rate of oxygen gas was set at 0 sccm to 400 sccm, and the applied voltage was set at 1 W to 1 kW. The components of the thin film were measured using EDX.

Next, a switch element was produced using each of the targets for film deposition in Examples 1, 2, 5, and 8 and Comparative Example 1. First, a 50 nm thick W electrode was deposited on a Si/SiO₂ substrate. Next, a 100 nm thick SiO₂ insulating layer was deposited on the W electrode. Thereafter, using a focused ion beam system (JIB-4600F by JEOL), a 500 nm diameter hole was formed in the SiO₂ insulating layer and the W electrode. Next, a 150 nm thick switch layer was formed into the formed hole. Finally, a 150 nm thick W electrode was further deposited on the switch layer, thus producing a switch element. The film deposition was conducted by Ar sputtering under a reduced-pressure atmosphere. In doing so, the film deposition was conducted by setting the substrate temperature at 15° C. to 400° C., the flow rate of Ar gas at 2 sccm to 1000 sccm, the flow rate of oxygen gas at 0 sccm to 400 sccm, and the applied voltage at 1 W to 1 kW. In the case of using the target for film deposition in Example 1, the components of the obtained switch layer were, in terms of atomic %, 17.7% Ge, 6.3% Ga, 3.8% Ag, and 72.2% Te. The components of the switch layer were measured using EDX.

The ON/OFF current ratio x was determined in the following manner. First, a 0 V to 5 V voltage was applied to the switch element to measure the values of current that flowed through the switch element and the threshold voltage. Next, the value of the ON current was divided by the value of the OFF current, thus obtaining the ON/OFF current ratio. The value of the ON current adopted was a value of a current that flowed through the switch element upon application of a voltage not less than the threshold voltage thereto. The value of the OFF current adopted was a value of a current that flowed through the switch element upon application of one-half the threshold voltage thereto. The results are shown in Table 8.

TABLE 8

| | Ex. 1 | Ex. 2 | Ex. 5 | Ex. 8 | CEx. 1 |
|---|---|---|---|---|---|
| ON/OFF Current | 4.7 | 5.3 | 4.6 | 4.9 | No |
| Ratio log₁₀x | | | | | switching |

As shown in Table 8, in each of the switch elements produced using the targets for film deposition in Examples 1, 2, 5, and 8, the ON/OFF current ratio log₁₀x was not less than 4.6 and therefore exhibited an excellent switching behavior. On the other hand, the switch element in Comparative Example 1 did not exhibit any switching behavior.

### INDUSTRIAL APPLICABILITY

The target for film deposition and the method for producing a functional layer, both according to the present invention, can be used suitably for production of a large-capacity memory device and an OTS element exhibiting a stable switching behavior. Particularly, they can suitably produce a functional layer, such as a variable-resistance layer or a phase-change layer.

### REFERENCE SIGNS LIST

1, 11 first electrode
2, 12 second electrode
3 switch layer
4 memory layer
5 insulator
10, 21 switch element
20 memory element
30 word line
40 bit line
100, 200, 101, 201 memory device

1. A target for film deposition containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb.

2. A target for film deposition made of a bulk chalcogenide glass that contains, in terms of atomic %, 0.1% to 50% Ge, 40% to 90% Te, and 1% to 59% Si+Al+Ga+Sn+Bi+Cu+Ag+Zn+Y+In+Ca+Mg and is substantially free of Sb.

3. A target for film deposition containing, in terms of atomic %, 0.1% to 50% Ge, 40% to 90% Te, and 1% to 59% Si+Al+Ga+Sn+Bi+Cu+Ag+Zn+Y+In+Ca+Mg, being substantially free of Sb, and containing a crystal portion.

4. The target for film deposition according to claim 1, having a relative density of not less than 90%.

5. The target for film deposition according to claim 1, having an oxygen content of, in terms of atomic %, not less than 0.001 ppm and less than 1%.

6. The target for film deposition according to claim 1, wherein a difference Δ (Tm−Tx) between a crystalline melting point Tm and a crystallization temperature Tx is not higher than 500° C.

7. The target for film deposition according to claim 1, being used for production of a variable-resistance layer.

8. The target for film deposition according to claim 1, having a disc shape with a diameter of 20 mm to 300 mm, a thickness of 1 mm to 100 mm, and a surface roughness of less than 500 μm.

9. The target for film deposition according to claim 1, further comprising a substrate.

10. A method for producing a functional layer using a target for film deposition,
the target for film deposition being made of a bulk chalcogenide glass containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb,
the method comprising producing a functional layer containing, in terms of atomic %, 0.1% to 50% Ge, 40% to 90% Te, and 1% to 59% Si+Al+Ga+Sn+Bi+Cu+Ag+Zn+Y+In+Ca+Mg and substantially free of Sb.

11. The method for producing a functional layer according to claim 10, wherein a second target for film deposition is further provided.

12. The method for producing a functional layer according to claim 10, wherein the functional layer is a variable-resistance layer.

13. The method for producing a functional layer according to claim 10, wherein the functional layer is a phase-change layer.

14. A method for producing a functional layer using a plurality of targets for film deposition, wherein
the targets for film deposition include a target for film deposition made of a Ga alloy or a Ga compound, and
the functional layer is a variable-resistance layer or a phase-change layer each of which contains, in terms of atomic %, 0.1% to 50% Ge, 0.1% to 50% Ga, and 40% to 90% Te.

15. The method for producing a functional layer according to claim 10, wherein the functional layer is substantially free of Sb.
